(19) United States
(12) Patent Application Publication
(10) Pub. No.: US 2024/0251536 A1
(43) Pub. Date: Jul. 25, 2024

(54) ELECTROMAGNETIC WAVE ABSORBER

(71) Applicant: Industrial Technology Research Institute, Hsinchu (TW)

(72) Inventors: Chun-Pin Wu, Tainan City (TW); Shi-Yuan Tong, Hsinchu County (TW); Wen-Song Ko, Hsinchu City (TW); Chun-An Lu, Taipei City (TW)

(73) Assignee: Industrial Technology Research Institute, Hsinchu (TW)

(21) Appl. No.: 18/393,719

(22) Filed: Dec. 22, 2023

Related U.S. Application Data
(60) Provisional application No. 63/434,940, filed on Dec. 23, 2022.

(51) Int. Cl. H05K 9/00

(52) U.S. Cl. CPC H05K 9/0088; H05K 9/0075; H05K 9/0084

(57) ABSTRACT

An electromagnetic wave absorber including a substrate and a plurality of magnetic material bodies is provided. The plurality of magnetic material bodies are disposed on the substrate in an array, so that the electromagnetic wave absorber has a plurality of electromagnetic wave absorption frequencies in addition to an electromagnetic wave characteristic frequency of the plurality of magnetic material bodies. A ratio of one of the plurality of electromagnetic wave absorption frequencies to the electromagnetic wave characteristic frequency is greater than 1 and is less than or equal to 6.

### CROSS-REFERENCE TO RELATED APPLICATION

This application claims the priority benefit of U.S. provisional application Ser. No. 63/434,940, filed on Dec. 23, 2022. The entirety of the above-mentioned patent application is hereby incorporated by reference herein and made a part of this specification.

### TECHNICAL FIELD

The disclosure relates to a material that can suppress electromagnetic interference, and in particular, relates to an electromagnetic wave absorber.

### BACKGROUND

With the continuous development of communication technology, designing an electronic component module to be equipped with characteristics such as high density, thinness, ultra-high frequency, and multi-functions, has become a trend. However, the distances among the electronic components in the abovementioned electronic component module may thereby decrease, so strong electromagnetic interference (EMI) may be generated among the components.

Currently, solutions to the above electromagnetic interference problem include coating of a metal layer on the outer surface of the electronic component module to reflect the electromagnetic waves, so as to achieve the effect of electromagnetic interference suppression. However, this solution still cannot reduce the radiated electromagnetic interference generated inside the electronic component module nor the high-order harmonics generated due to the resonance effect.

Regarding the abovementioned radiated electromagnetic interference and the high-order harmonics generated due to the resonance effect, at present, in order to reduce the phenomenon of electromagnetic interference, a specific magnetic material is formed in the electronic component module for absorption. However, the electromagnetic waves that the currently-available magnetic materials can absorb are of low frequency (<50 GHz), so it is difficult for the currently-available magnetic materials to be applied to the next-generation communication systems (sixth-generation communication systems).

### SUMMARY

The disclosure provides an electromagnetic wave absorber capable of reducing the phenomenon of electromagnetic interference.

An embodiment of the disclosure provides an electromagnetic wave absorber including a substrate and a plurality of magnetic material bodies. The plurality of magnetic material bodies are disposed on the substrate in an array, so that the electromagnetic wave absorber has a plurality of electromagnetic wave absorption frequencies in addition to an electromagnetic wave characteristic frequency of the plurality of magnetic material bodies. A ratio of one of the plurality of electromagnetic wave absorption frequencies to the electromagnetic wave characteristic frequency is greater than 1 and less than or equal to 6.

Based on the above, the electromagnetic wave absorber provided by the disclosure can absorb electromagnetic waves in at least two frequency bands. In detail, first the electromagnetic wave absorber provided by the disclosure can absorb electromagnetic waves with the same or similar frequency as the electromagnetic wave characteristic frequency of the magnetic material bodies. Further, the plurality of magnetic material bodies are disposed on the substrate in an array in the disclosure, so that a surface lattice resonance effect occurs between adjacent magnetic material bodies. As such, the electromagnetic wave absorber provided by the disclosure can have multiple electromagnetic wave absorption frequencies in addition to the abovementioned electromagnetic wave characteristic frequency, and therefore, can absorb high-frequency electromagnetic waves in other frequency bands (the frequencies of which are greater than the electromagnetic wave characteristic frequency of the magnetic material bodies). Based on the above, the electromagnetic wave absorber of the disclosure can be used in the next-generation communication systems to reduce the phenomenon of electromagnetic interference generated in the systems.

### BRIEF DESCRIPTION OF THE DRAWINGS

FIG. 1A is a schematic three-dimensional view of an electromagnetic wave absorber according to the first embodiment of the disclosure.

FIG. 1B is a side view of the electromagnetic wave absorber according to FIG. 1A.

FIG. 1C is a schematic partial cross-sectional view of an antenna module according to an embodiment of the disclosure.

FIG. 2A is a schematic three-dimensional view of an electromagnetic wave absorber according to the second embodiment of the disclosure.

FIG. 2B is a side view of the electromagnetic wave absorber according to FIG. 2A.

FIG. 3 is a schematic three-dimensional view of an electromagnetic wave absorber according to the third embodiment of the disclosure.

FIG. 4A is a schematic three-dimensional view of an electromagnetic wave absorber according to the fourth embodiment of the disclosure.

FIG. 4B is a side view of the electromagnetic wave absorber according to FIG. 4A.

FIG. 5A is a schematic three-dimensional view of an electromagnetic wave absorber according to the fifth embodiment of the disclosure.

FIG. 5B is a side view of the electromagnetic wave absorber according to FIG. 5A.

FIG. 6A to FIG. 6C respectively illustrate absorption spectrum graphs of electromagnetic wave absorbers of Example 1 to Example 3 of the disclosure.

FIG. 7A to FIG. 7C respectively illustrate absorption spectrum graphs of electromagnetic wave absorbers of Example 4 to Example 6 of the disclosure.

FIG. 8A to FIG. 8C respectively illustrate absorption spectrum graphs of electromagnetic wave absorbers of Example 7 to Example 9 of the disclosure.

FIG. 9A to FIG. 9B respectively illustrate absorption spectrum graphs of electromagnetic wave absorbers of Example 10 and Example 11 of the disclosure.

FIG. 10A to FIG. 10D respectively illustrate absorption spectrum graphs of electromagnetic wave absorbers of Example 12 to Example 15 of the disclosure.

FIG. 11A to FIG. 11C respectively illustrate absorption spectrum graphs of electromagnetic wave absorbers of Example 16 to Example 18 of the disclosure.

FIG. 12A to FIG. 12B respectively illustrate absorption spectrum graphs of electromagnetic wave absorbers of Example 19 and Example 20 of the disclosure.

FIG. 13A to FIG. 13C respectively illustrate absorption spectrum graphs of electromagnetic wave absorbers of Example 21 to Example 23 of the disclosure.

FIG. 14A to FIG. 14C respectively illustrate absorption spectrum graphs of electromagnetic wave absorbers of Example 24 to Example 26 of the disclosure.

FIG. 15 illustrates an absorption spectrum graph of an electromagnetic wave absorber of Example 27 of the disclosure.

FIG. 16A to FIG. 16B respectively illustrate absorption spectrum graphs of electromagnetic wave absorbers of Comparative Example 1 and Comparative Example 2.

### DETAILED DESCRIPTION OF DISCLOSED EMBODIMENTS

The disclosure may be understood by referring to the following detailed description with reference to the accompanying drawings. It is noted that for comprehension of the reader and simplicity of the drawings, in the drawings provided in the disclosure, only a part of the electronic device is shown, and certain devices in the drawings are not necessarily drawn to actual scale. Moreover, the quantity and the size of each device in the drawings are only schematic and exemplary and are not intended to limit the scope of protection provided in the disclosure.

Directional terminologies mentioned in the disclosure, such as “top”, “bottom”, “front”, “back”, “left”, “right”, and so forth, refer to directions in the reference accompanying drawings. Accordingly, the directional terminologies provided herein serve to describe rather than limiting the disclosure. In the accompanying drawings, each figure illustrates methods applied in particular embodiments and general features of structures and/or materials in the embodiments. However, these figures should not be construed or defined as the scope covered by the particular embodiments. For instance, relative dimensions, thicknesses, and positions of various layers, regions, and/or structures may be reduced or enlarged for clarity.

The terminologies “about”, “equal to”, “equivalent to” or “same”, “substantially” or “approximately” are generally interpreted as being within 10% of a given value or range, or interpreted as being within 5%, 3%, 2%, 1%, or 0.5% of a given value or range.

It should be understood that the following embodiments may replace, reorganize, and mix the features in several different embodiments to complete other embodiments without departing from the spirit of the disclosure. As long as the features of the embodiments do not violate the spirit of the disclosure or conflict each other, they may be mixed and matched as desired.

Reference will now be made in detail to the exemplary embodiments of the disclosure, and the same reference numbers are used in the drawings and descriptions to indicate the same or similar parts.

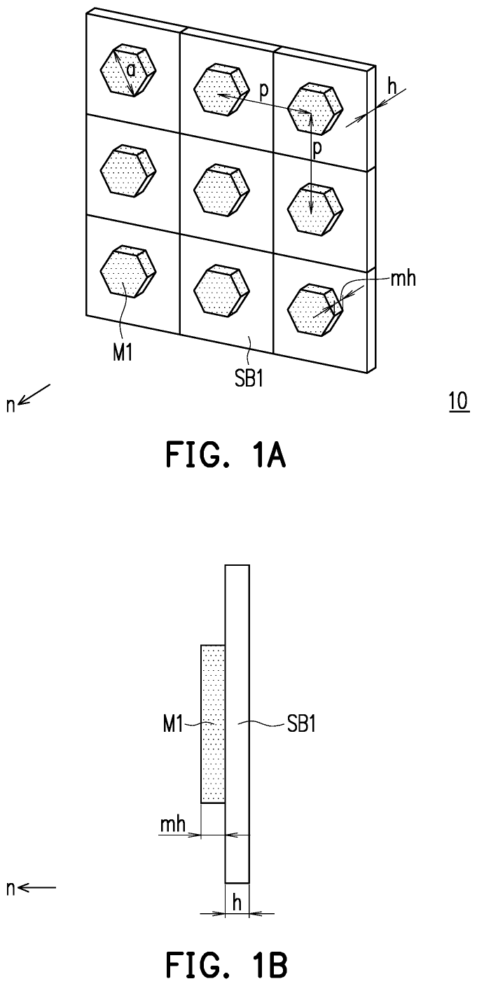

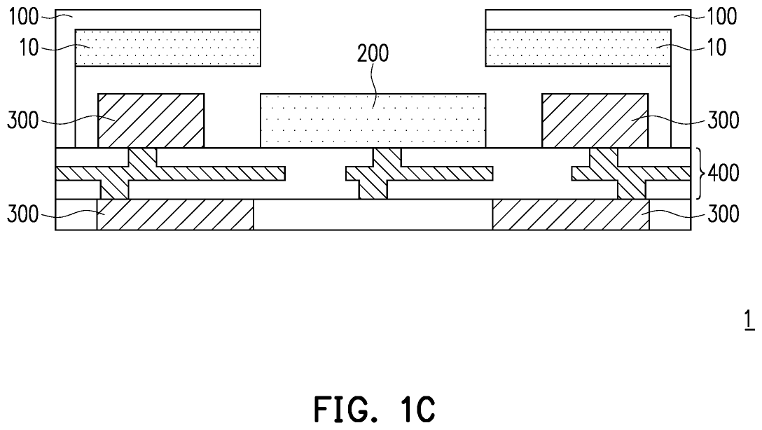

FIG. 1A is a schematic three-dimensional view of an electromagnetic wave absorber according to the first embodiment of the disclosure, and FIG. 1B is a side view of the electromagnetic wave absorber according to FIG. 1A.

With reference to FIG. 1A and FIG. 1B together, an electromagnetic wave absorber 10 of this embodiment includes a substrate SB1 and a plurality of magnetic material bodies M1. However, the formation of the electromagnetic wave absorber 10 of the disclosure is not limited thereto.

The substrate SB1 may be used to carry, for example, the plurality of magnetic material bodies M1. In some embodiments, a material of the substrate SB1 may include resin, but the disclosure is not limited thereto. In other embodiments, the material of the substrate SB1 and a material of the magnetic material bodies M1 are the same as each other. In still other embodiments, the material of the substrate SB1 may include a conductive material. In addition, in some embodiments, the substrate SB1 may include a single-layer structure or a multi-layer structure. In this embodiment, the substrate SB1 is a single-layer structure, but the disclosure is not limited thereto.

In some embodiments, a thickness h of the substrate SB1 is 0.05 mm to 50 mm or 0.1 mm to 5 mm. For example, the thickness h of the substrate SB1 may be 0.4 mm to 0.8 mm, but the disclosure is not limited thereto.

In some embodiments, the substrate SB1 has a dielectric coefficient of 1 to 50. For instance, the dielectric coefficient of the substrate SB1 may be 2 to 5, but the disclosure is not limited thereto.

The plurality of magnetic material bodies M1 are disposed on the substrate SB1, for example, and can effectively absorb incident electromagnetic waves. In detail, a characteristic frequency of the plurality of magnetic material bodies M1 can match frequencies of electromagnetic waves to be absorbed, so that the electromagnetic waves incident on the plurality of magnetic material bodies M1 can be attenuated or eliminated through the resonance absorption phenomenon. In this embodiment, the plurality of magnetic material bodies M1 are arranged in an array on the substrate SB1. Through the above design, the adjacent magnetic material bodies M1 may generate a surface lattice resonance effect between each other, so that a characteristic frequency greater than the plurality of magnetic material bodies M1 themselves can be absorbed.

In general, by arranging the plurality of magnetic material bodies M1 on the substrate SB1 in an array, the electromagnetic wave absorber 10 of this embodiment can absorb electromagnetic waves in at least two frequency bands. In other words, in addition to the electromagnetic wave characteristic frequency of the plurality of magnetic material bodies M1, a plurality of electromagnetic wave absorption frequencies in addition to the electromagnetic wave characteristic frequency are further added and included in the electromagnetic wave absorber 10 of this disclosure, so that the electromagnetic wave absorber 10 of this disclosure may be applied to absorb electromagnetic wave frequency bands of higher frequencies.

In some embodiments, the electromagnetic wave characteristic frequency of the plurality of magnetic material bodies M1 is 0.1 MHz to 1 THz. For instance, the electromagnetic wave characteristic frequency of the plurality of magnetic material bodies M1 may be 0.5 GHz, 50 GHz, 150 GHz, or 250 GHz, but the disclosure is not limited thereto.

In some embodiments, the material of the plurality of magnetic material bodies M1 includes a magnetic element oxide. The magnetic element may be iron (Fe), cobalt (Co), nickel (Ni), manganese (Mn), chromium (Cr), gadolinium (Gd), terbium (Tb), dysprosium (Dy), holmium (Ho), erbium (Er), thulium (Tm), or a combination of the above elements. For instance, the material of the plurality of magnetic material bodies M1 may be an iron oxide, a cobalt oxide, or a cobalt iron oxide, but the disclosure is not limited thereto. In some other embodiments, the material of the plurality of magnetic material bodies M1 may include a magnetic element oxide doped with other elements, which may be represented by the following formula, for example: MxFe3-x oxide, where M is an element doped into a magnetic element oxide (e.g., iron oxide), the oxidation number of M may be +1, +2, +3, +4, +5, or +6, and x may be greater than or equal to 0 and less than 1 and may be, for example, 0.1, 0.15, 0.2, 0.25, 0.3, 0.35, 0.4, 0.45, 0.5, 0.55, 0.6, 0.65, 0.7, 0.75, 0.8, 0.85, 0.9, or 0.95.

In some embodiments, the element doped into the iron oxide may be independently selected from at least one of the group consisting of molybdenum (Mo), zirconium (Zr), magnesium (Mg), calcium (Ca), yttrium (Y), titanium (Ti), and silver (Ag), aluminum (Al), barium (Ba), gallium (Ga), rhodium (Rh), nickel (Ni), iron (Fe), cobalt (Co), nickel (Ni), manganese (Mn), chromium (Cr), gadolinium (Gd), terbium (Tb), dysprosium (Dy), holmium (Ho), erbium (Er), thulium (Tm), and lanthanide elements. In this embodiment, the element doped into the iron oxide includes barium (Ba), but the disclosure is not limited thereto. Based on the above, by doping an appropriate element into the iron oxide, the characteristic frequency of the plurality of magnetic material bodies M1 may be changed for absorbing electromagnetic waves with different frequencies.

In some embodiments, a shape of each magnetic material body M1 may include a polygonal prism shape, a cylindrical prism shape, a polygonal cone shape, a conical shape, or a combination thereof. Herein, polygonal shapes of the polygonal prism shape and the polygonal cone shape may include a trigonal shape, a quadrilateral shape, a hexagonal shape, an octagonal shape, or a dodecagonal shape. In this embodiment, as shown in FIG. 1A and FIG. 1B, the shape of each magnetic material body M1 is a hexagonal prism, but the disclosure is not limited thereto.

In some embodiments, a thickness mh of one of the magnetic material bodies M1 is 0.01 mm to 50 mm. For instance, the thickness mh of one of the plurality of magnetic material bodies M1 may be 0.05 mm to 0.5 mm, but the disclosure is not limited thereto.

In some embodiments, a dielectric coefficient of one of the magnetic material bodies M1 is 1 to 50. For instance, the dielectric coefficient of one of the plurality of magnetic material bodies M1 may be 2 to 20, but the disclosure is not limited thereto.

In some embodiments, one of the plurality of magnetic material bodies M1 has a width a in a normal direction n of the substrate SB. The width a of each magnetic material body M1 conforms to, for example, the following relational expression 1:
a=λ_{F}_{ₘ}*fp (relational expression 1), where a is the width of the magnetic material body M1, λ_{F}_{ₘ} is a wavelength of the electromagnetic wave characteristic frequency of the magnetic material bodies M1, and fp is a constant and may be 0.01 to 50. In some embodiments, fp may be 0.02 to 2.

Taking the embodiment shown in FIG. 1A and FIG. 1B as an example, the shape of one of the plurality of magnetic material bodies M1 in the normal direction n of the substrate SB1 is a hexagon and has a maximum width a, but the disclosure is not limited thereto.

In some embodiments, a pitch p is provided between adjacent magnetic material bodies M1. The pitch p between adjacent magnetic material bodies M1 conforms to, for example, the following relational expression 2:
p=sp*λ_{F}_{ₛ}/\sqrt{(εₛμₛ)} (relational expression 2), where p is the pitch between adjacent magnetic material bodies M1, λ_{F}_{ₛ} is a wavelength of twice the electromagnetic wave characteristic frequency of the magnetic material bodies M1, εₛ is a dielectric coefficient of the substrate, μₛ is a magnetic permeability coefficient of the substrate, and sp is a constant and may be 0.1 to 2.

Based on the above, by allowing the electromagnetic wave absorber 10 of this embodiment to have the above design, the electromagnetic wave absorber 10 may have multiple electromagnetic wave absorption frequency bands and electromagnetic wave absorption frequency bands of higher frequencies, so that high frequency electromagnetic waves may be effectively absorbed. The electromagnetic wave absorber 10 of this embodiment may therefore be applied more widely, that is, may be applied to the next generation communication systems.

It is worth noting that the electromagnetic wave characteristic frequency and an electromagnetic wave absorption rate of the electromagnetic wave absorber 10 may be known by conducting the following experimental examples to evaluate the performance of the electromagnetic wave absorber 10 in the electromagnetic wave absorption spectrum, and description thereof is not provided herein.

FIG. 1C is a schematic partial cross-sectional view of an antenna module according to an embodiment of the disclosure.

With reference to FIG. 1C, the electromagnetic wave absorber 10 of this embodiment may be applied in an antenna module 1. In some embodiments, the antenna module 1 may include the electromagnetic wave absorber 10, a radome 100, an antenna component 200, a plurality of electronic components 300, and a redistribution structure 400, but the disclosure is not limited thereto.

The radome 100 may be used to, for example, protect each component in the antenna module 1 from environmental influences. The electromagnetic wave absorber 10 may be disposed on, for example, the radome 100, for example, to reduce electromagnetic wave interference generated among various components (e.g., the antenna component 200 and the electronic components 300). The antenna component 200 and the plurality of electronic components 300 may be electrically connected to each other through, for example, the redistribution structure 400.

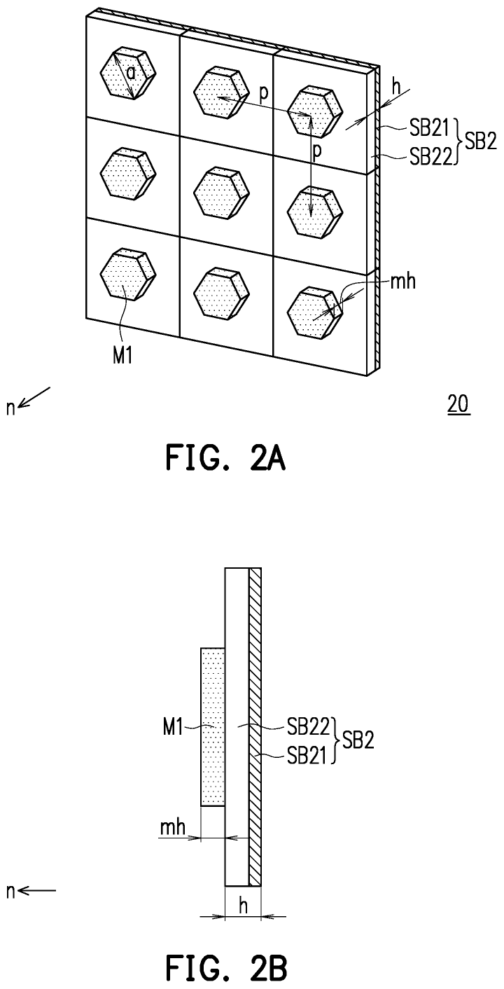

FIG. 2A is a schematic three-dimensional view of an electromagnetic wave absorber according to the second embodiment of the disclosure, and FIG. 2B is a side view of the electromagnetic wave absorber according to FIG. 2A. It should be mentioned that the reference numbers and some content provided in the embodiments shown in FIG. 1A and FIG. 1B may be applied in the embodiments shown in FIG. 2A and FIG. 2B, where the same or similar reference numbers serve to denote the same or similar elements, and the description of the same technical content is omitted.

With reference to FIG. 2A and FIG. 2B together, the main difference between an electromagnetic wave absorber 20 of this embodiment and the electromagnetic wave absorber 10 of the above embodiment is: a substrate SB2 includes a multi-layer structure.

In detail, in this embodiment, the substrate SB2 includes a first substrate SB21 and a second substrate SB22 stacked on each other, and the plurality of magnetic material bodies M1 are disposed on the second substrate SB22. In other words, the plurality of magnetic material bodies M1 and the first substrate SB21 are disposed on two opposite surfaces of the second substrate SB22, for example.

In this embodiment, a material of the first substrate SB21 includes a conductive material. For instance, the material of the first substrate SB21 may include copper or aluminum, but the disclosure is not limited thereto. In this embodiment, a material of the second substrate SB22 includes resin, which may be the same as or similar to the material of the substrate SB1 in the above embodiment, so description thereof is not repeatedly provided herein.

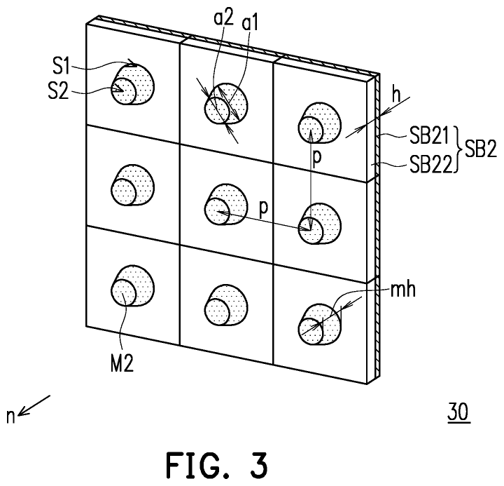

FIG. 3 is a schematic three-dimensional view of an electromagnetic wave absorber according to the third embodiment of the disclosure. It should be mentioned that the reference numbers and some content provided in the embodiment shown in FIG. 1A may be applied in the embodiment shown in FIG. 3, where the same or similar reference numbers serve to denote the same or similar elements, and the description of the same technical content is omitted.

With reference to FIG. 3, the main difference between an electromagnetic wave absorber 30 of this embodiment and the electromagnetic wave absorber 10 of the above embodiment is: a shape of each magnetic material body M2 is a truncated cone.

In detail, in this embodiment, each magnetic material body M2 has a bottom surface S1 and a top surface S2 in the normal direction n of the substrate SB1. Herein, the bottom surface S1 has a width a1 that is greater than or equal to a width a2 of the top surface S2, so that a ratio of a cross-sectional area of the bottom surface S1 of the magnetic material body M2 to a cross-sectional area of the top surface S2 is ≥1. In some embodiments, a ratio of an area of the bottom surface S1 to an area of the top surface S2 (i.e., a ratio of a square of the width a1 to a square of the width a2) is 1 to 4.

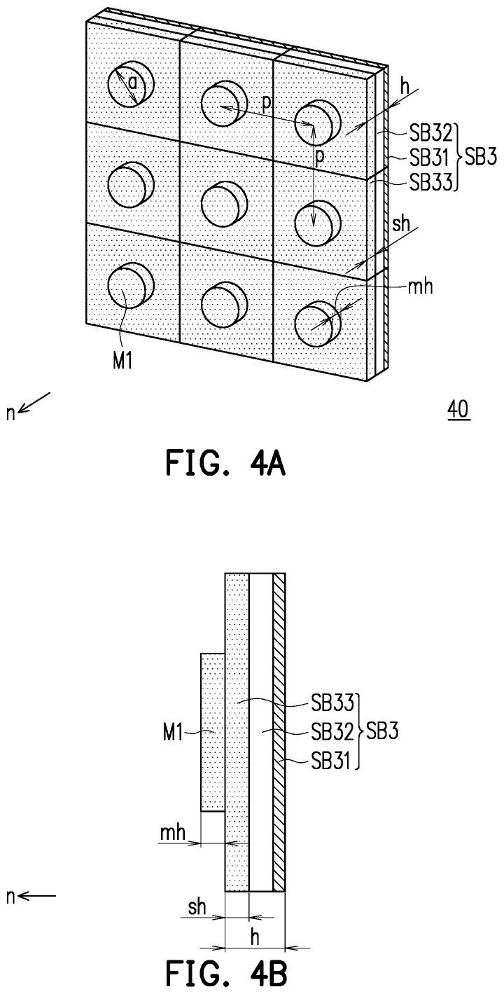

FIG. 4A is a schematic three-dimensional view of an electromagnetic wave absorber according to the fourth embodiment of the disclosure, and FIG. 4B is a side view of the electromagnetic wave absorber according to FIG. 4A. It should be mentioned that the reference numbers and some content provided in the embodiments shown in FIG. 1A and FIG. 1B may be applied in the embodiments shown in FIG. 4A and FIG. 4B, where the same or similar reference numbers serve to denote the same or similar elements, and the description of the same technical content is omitted.

With reference to FIG. 4A and FIG. 4B together, the main difference between an electromagnetic wave absorber 40 of this embodiment and the electromagnetic wave absorber 10 of the above embodiment is: a substrate SB3 includes a multi-layer structure.

In detail, in this embodiment, the substrate SB3 includes a first substrate SB31, a second substrate SB32, and a third substrate SB33 stacked on one another, and the plurality of magnetic material bodies M1 are disposed on the third substrate SB33.

In this embodiment, a material of the first substrate SB31 includes a conductive material. For instance, the material of the first substrate SB31 may include copper or aluminum, but the disclosure is not limited thereto. In this embodiment, a material of the second substrate SB32 includes resin, which may be the same as or similar to the material of the substrate SB1 in the above embodiment, so description thereof is not repeatedly provided herein. In this embodiment, a material of the third substrate SB33 and the material of the magnetic material bodies M1 are the same.

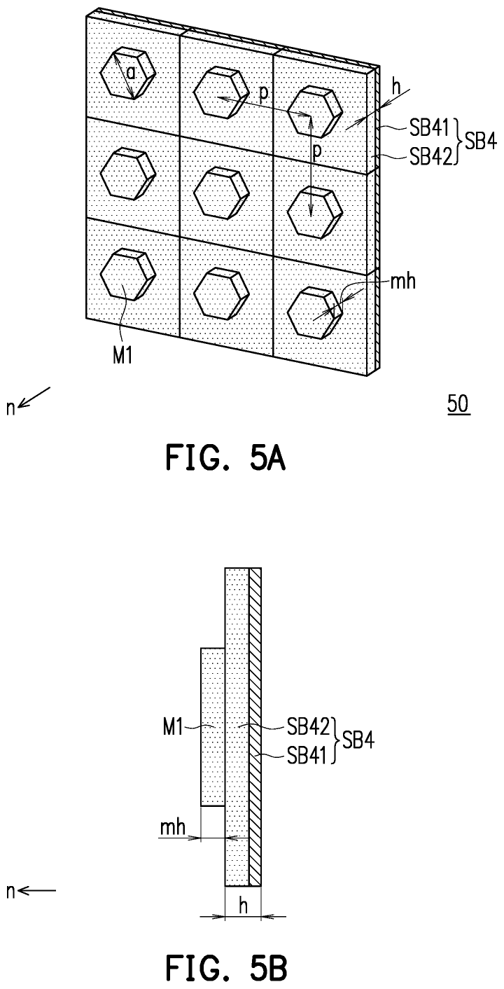

FIG. 5A is a schematic three-dimensional view of an electromagnetic wave absorber according to the fifth embodiment of the disclosure, and FIG. 5B is a side view of the electromagnetic wave absorber according to FIG. 5A. It should be mentioned that the reference numbers and some content provided in the embodiments shown in FIG. 1A and FIG. 1B may be applied in the embodiments shown in FIG. 5A and FIG. 5B, where the same or similar reference numbers serve to denote the same or similar elements, and the description of the same technical content is omitted.

With reference to FIG. 5A and FIG. 5B together, the main difference between an electromagnetic wave absorber 50 of this embodiment and the electromagnetic wave absorber 10 of the above embodiment is: a substrate SB4 includes a multi-layer structure.

In detail, in this embodiment, the substrate SB4 includes a first substrate SB41 and a second substrate SB42 stacked on each other, and the plurality of magnetic material bodies M1 are disposed on the second substrate SB42.

In this embodiment, a material of the first substrate SB41 includes a conductive material. For instance, the material of the first substrate SB41 may include copper or aluminum, but the disclosure is not limited thereto. In this embodiment, a material of the second substrate SB42 and the material of the magnetic material bodies M1 are the same.

### EXPERIMENTAL EXAMPLES

The following experimental examples are used to illustrate the disclosure. But these experimental examples are provided for description only and are presented as examples and are not intended to be used to limit the scope of the disclosure.

In this experimental example, a terahertz time domain spectrometer (THz-TDS) is used to measure the electromagnetic wave absorption rate at each frequency of the electromagnetic wave absorber in the following examples.

### Example 1

In Example 1, the structure of the electromagnetic wave absorber 10 shown in FIG. 1A and FIG. 1B is used, and the following parameters are provided.

(1) The electromagnetic wave characteristic frequency of the magnetic material bodies M1 is 50 GHz (twice the electromagnetic wave characteristic frequency is 100 GHz). (2) The dielectric coefficient of each magnetic material body M1 is 4. (3) The dielectric coefficient of the substrate SB1 is 4.4. (4) The magnetic permeability coefficient of the substrate SB1 is 1. (5) fp in the relational expression 1 used to express the width of each magnetic material body M1 is 0.125. (6) sp in the relational expression 2 used to express the pitch p between adjacent magnetic material bodies M1 is 0.5. (7) The thickness h of the substrate SB1 is 0.4 mm. (8) The thickness mh of each magnetic material body M1 is 0.4 mm.

### Example 2

In Example 2, the structure of the electromagnetic wave absorber 10 shown in FIG. 1A and FIG. 1B is used. The parameters are substantially the same as those in Example 1, and the only difference is: (6) sp in the relational expression 2 used to express the pitch between adjacent magnetic material bodies M1 is 1.

### Example 3

In Example 3, the structure of the electromagnetic wave absorber 10 shown in FIG. 1A and FIG. 1B is used. The parameters are substantially the same as those in Example 1, and the only difference is: (6) sp in the relational expression 2 used to express the pitch between adjacent magnetic material bodies M1 is 1.5.

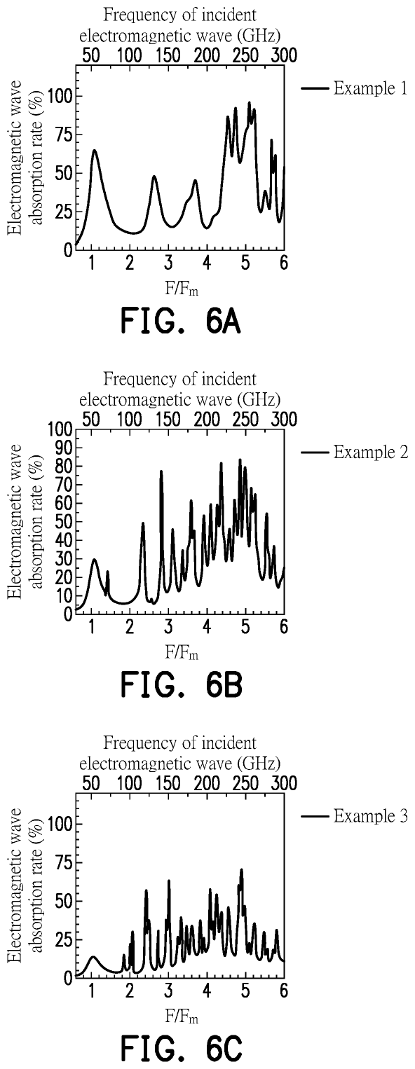

With the use of a terahertz time domain spectrometer, electromagnetic waves with different frequencies are incident on the electromagnetic wave absorber 10 of Example 1 to Example 3, so as to measure their electromagnetic wave absorption rates at each frequency, and the absorption spectrum graphs shown in FIG. 6A to FIG. 6C are produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 6A, FIG. 6A illustrates the absorption spectrum graph of the electromagnetic wave absorber 10 of Example 1, and the graph shows electromagnetic wave characteristic absorption peaks in multiple frequency bands. In detail, when F/Fₘ is 1 (F=50 GHZ), an electromagnetic wave absorption rate of approximately 64.3% is provided. When F/Fₘ is 2.63 (F=131.5 GHZ), an electromagnetic wave absorption rate of approximately 48.60% is provided. When F/Fₘ is 5.10 (F=255 GHZ), an absorption rate of approximately 96.35% is provided, which is the electromagnetic wave absorption peak with the strongest absorption intensity. When F/Fₘ is 5.97 (F=298.5 GHZ), an absorption rate of approximately 33.7% is provided, which is the electromagnetic wave absorption peak with the highest frequency.

With reference to FIG. 6B, FIG. 6B illustrates the absorption spectrum graph of the electromagnetic wave absorber 10 of Example 2, and the graph shows electromagnetic wave characteristic absorption peaks in multiple frequency bands. In detail, when F/Fₘ is 1 (F=50 GHZ), an electromagnetic wave absorption rate of approximately 29.5% is provided. When F/Fₘ is 1.42 (F=71 GHZ), an electromagnetic wave absorption rate of approximately 29.5% is provided. When F/Fₘ is 4.37 (F=218.5 GHZ), an absorption rate of approximately 83.2% is provided, which is the electromagnetic wave absorption peak with the strongest absorption intensity. When F/Fₘ is 5.98 (F=299 GHZ), an absorption rate of approximately 24.4% is provided, which is the electromagnetic wave absorption peak with the highest frequency.

With reference to FIG. 6C, FIG. 6C illustrates the absorption spectrum graph of the electromagnetic wave absorber 10 of Example 3, and the graph shows electromagnetic wave characteristic absorption peaks in multiple frequency bands. In detail, when F/Fₘ is 1 (F=50 GHZ), an electromagnetic wave absorption rate of approximately 13.9% is provided. When F/F is 1.84 (F=92 GHZ), an electromagnetic wave absorption rate of approximately 14.9% is provided. When F/Fₘ is 4.90 (F=245 GHZ), an absorption rate of approximately 70.2% is provided, which is the electromagnetic wave absorption peak with the strongest absorption intensity. When F/Fₘ is 5.82 (F=291 GHZ), an absorption rate of approximately 31.0% is provided, which is the electromagnetic wave absorption peak with the highest frequency.

It can be known from the absorption spectrum graphs of the electromagnetic wave absorber 10 of the above Example 1 to Example 3 that in addition to the electromagnetic wave characteristic frequency of the plurality of magnetic material bodies M1, the electromagnetic wave absorber 10 is also added with a plurality of electromagnetic wave absorption frequencies due to the surface lattice resonance effect. Therefore, the electromagnetic wave absorber 10 of Example 1 to Example 3 may have electromagnetic wave characteristic absorption peaks in multiple frequency bands.

Further, it can also be known from the above absorption spectrum graphs of the electromagnetic wave absorber 10 of Example 1 to Example 3 that the electromagnetic wave absorption rate of the first electromagnetic wave characteristic absorption peak (F/Fₘ=50 GHZ) decreases as sp in the relational expression 2 increases (i.e., the pitch p between adjacent magnetic material bodies M1 increases).

### Example 4

In Example 4, the structure of the electromagnetic wave absorber 10 shown in FIG. 1A and FIG. 1B is used. The parameters are substantially the same as those in Example 2, and the only difference is: (8) The thickness mh of each magnetic material body M1 is 0.05 mm.

### Example 5

In Example 5, the structure of the electromagnetic wave absorber 10 shown in FIG. 1A and FIG. 1B is used. The parameters are substantially the same as those in Example 4, and the only difference is: (8) The thickness mh of each magnetic material body M1 is 0.1 mm.

### Example 6

In Example 6, the structure of the electromagnetic wave absorber 10 shown in FIG. 1A and FIG. 1B is used. The parameters are substantially the same as those in Example 4, and the only difference is: (8) The thickness mh of each magnetic material body M1 is 0.5 mm.

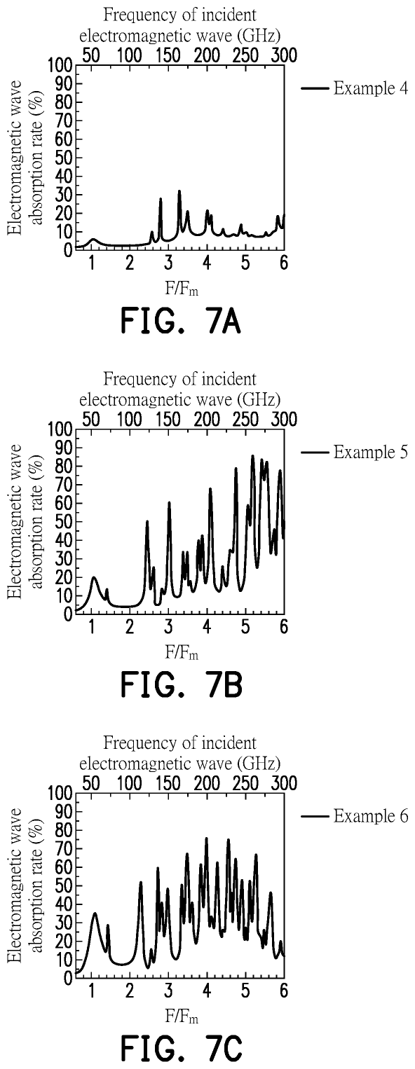

With the use of a terahertz time domain spectrometer, electromagnetic waves with different frequencies are incident on the electromagnetic wave absorber 10 of Example 4 to Example 6, so as to measure their electromagnetic wave absorption rates at each frequency, and the absorption spectrum graphs shown in FIG. 7A to FIG. 7C are produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 7A, FIG. 7A illustrates the absorption spectrum graph of the electromagnetic wave absorber 10 of Example 4, and the graph shows electromagnetic wave characteristic absorption peaks in multiple frequency bands. In detail, when F/Fₘ is 1 (F=50 GHZ), an electromagnetic wave absorption rate of approximately 6.7% is provided. When F/F is 2.56 (F=128 GHZ), an electromagnetic wave absorption rate of approximately 9.9% is provided. When F/Fₘ is 3.28 (F=164 GHZ), an absorption rate of approximately 31.9% is provided, which is the electromagnetic wave absorption peak with the strongest absorption intensity. When F/Fₘ is 6 (F=300 GHZ), an absorption rate of approximately 19.1% is provided, which is the electromagnetic wave absorption peak with the highest frequency.

With reference to FIG. 7B, FIG. 7B illustrates the absorption spectrum graph of the electromagnetic wave absorber 10 of Example 5, and the graph shows electromagnetic wave characteristic absorption peaks in multiple frequency bands. In detail, when F/Fₘ is 1 (F=50 GHZ), an electromagnetic wave absorption rate of approximately 20.3% is provided. When F/F is 1.4 (F=70 GHZ), an electromagnetic wave absorption rate of approximately 13.6% is provided. When F/Fₘ is 5.18 (F=259 GHZ), an absorption rate of approximately 85.4% is provided, which is the electromagnetic wave absorption peak with the strongest absorption intensity. When F/F is 5.89 (F=294.5 GHZ), an absorption rate of approximately 77.9% is provided, which is the electromagnetic wave absorption peak with the highest frequency.

With reference to FIG. 7C, FIG. 7C illustrates the absorption spectrum graph of the electromagnetic wave absorber 10 of Example 6, and the graph shows electromagnetic wave characteristic absorption peaks in multiple frequency bands. In detail, when F/Fₘ is 1 (F=50 GHZ), an electromagnetic wave absorption rate of approximately 35.5% is provided. When F/F is 1.43 (F=71.5 GHZ), an electromagnetic wave absorption rate of approximately 28.6% is provided. When F/Fₘ is 3.98 (F=199 GHZ), an absorption rate of approximately 75.7% is provided, which is the electromagnetic wave absorption peak with the strongest absorption intensity. When F/Fₘ is 5.9 (F=295 GHZ), an absorption rate of approximately 19.6% is provided, which is the electromagnetic wave absorption peak with the highest frequency.

It can be known from the absorption spectrum graphs of the electromagnetic wave absorber 10 of the above Example 4 to Example 6 that in addition to the electromagnetic wave characteristic frequency of the plurality of magnetic material bodies M1, the electromagnetic wave absorber 10 is also added with a plurality of electromagnetic wave absorption frequencies due to the surface lattice resonance effect. Therefore, the electromagnetic wave absorber 10 of Example 4 to Example 6 may have electromagnetic wave characteristic absorption peaks in multiple frequency bands.

Further, it can also be known from the above absorption spectrum graphs of the electromagnetic wave absorber 10 of Example 4 to Example 6 that the electromagnetic wave absorption rate of the first electromagnetic wave characteristic absorption peak (F/Fₘ=50 GHZ) increases as the thickness mh of each magnetic material body M1 increases. Further, when the thickness mh increases from 0.1 mm to 0.5 mm, the electromagnetic wave absorption peak with the strongest absorption intensity shifts to low frequency.

### Example 7

In Example 7, the structure of the electromagnetic wave absorber 20 shown in FIG. 2A and FIG. 2B is used, and the following parameters are provided.

(1) The electromagnetic wave characteristic frequency of the magnetic material bodies M1 is 50 GHz (twice the electromagnetic wave characteristic frequency is 100 GHz). (2) The dielectric coefficient of each magnetic material body M1 is 4. (3) The dielectric coefficient of the substrate SB2 is 4.1. (4) The magnetic permeability coefficient of the substrate SB2 is 1. (5) fp in the relational expression 1 used to express the width of each magnetic material body M1 is 0.05. (6) sp in the relational expression 2 used to express the pitch p between adjacent magnetic material bodies M1 is 1. (7) The thickness h of the substrate SB2 is 0.4 mm. (8) The thickness mh of each magnetic material body M1 is 0.5 mm.

### Example 8

In Example 8, the structure of the electromagnetic wave absorber 20 shown in FIG. 2A and FIG. 2B is used. The parameters are substantially the same as those in Example 7, and the only difference is: (5) fp in the relational expression 1 used to express the width of each magnetic material body M1 is 0.15.

### Example 9

In Example 9, the structure of the electromagnetic wave absorber 20 shown in FIG. 2A and FIG. 2B is used. The parameters are substantially the same as those in Example 7, and the only difference is: (5) fp in the relational expression 1 used to express the width of each magnetic material body M1 is 0.25.

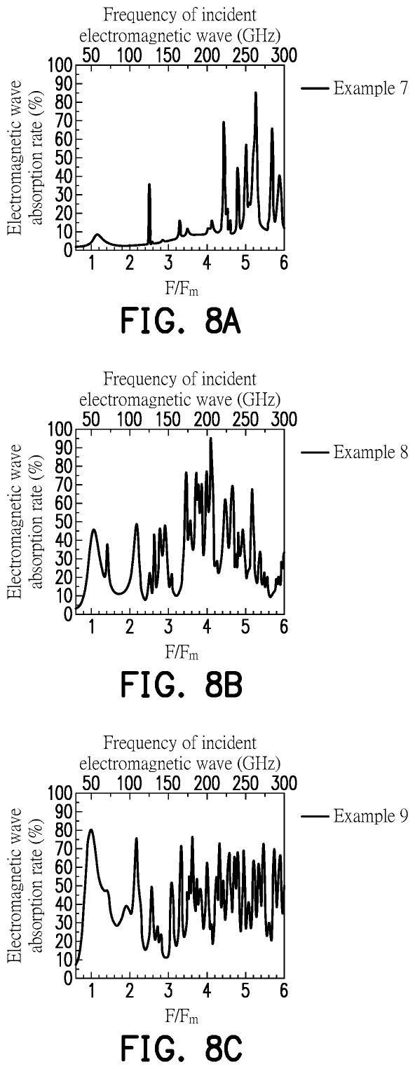

With the use of a terahertz time domain spectrometer, electromagnetic waves with different frequencies are incident on the electromagnetic wave absorber 20 of Example 7 to Example 9, so as to measure their electromagnetic wave absorption rates at each frequency, and the absorption spectrum graphs shown in FIG. 8A to FIG. 8C are produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 8A, FIG. 8A illustrates the absorption spectrum graph of the electromagnetic wave absorber 20 of Example 7, and the graph shows electromagnetic wave characteristic absorption peaks in multiple frequency bands. In detail, when F/Fₘ is 1 (F=50 GHZ), an electromagnetic wave absorption rate of approximately 8.14% is provided. When F/Fₘis 2.5 (F=100 GHZ), an electromagnetic wave absorption rate of approximately 35.5% is provided. When F/Fₘ is 5.25 (F=262.5 GHZ), an absorption rate of approximately 85.2% is provided, which is the electromagnetic wave absorption peak with the strongest absorption intensity. When F/Fₘ is 5.89 (F=294.5 GHZ), an absorption rate of approximately 37.3% is provided, which is the electromagnetic wave absorption peak with the highest frequency.

With reference to FIG. 8B, FIG. 8B illustrates the absorption spectrum graph of the electromagnetic wave absorber 20 of Example 8, and the graph shows electromagnetic wave characteristic absorption peaks in multiple frequency bands. In detail, when F/Fₘ is 1 (F=50 GHZ), an electromagnetic wave absorption rate of approximately 45.9% is provided. When F/Fₘis 1.4 (F=70 GHZ), an electromagnetic wave absorption rate of approximately 48.1% is provided. When F/Fₘ is 4.1 (F=205 GHZ), an absorption rate of approximately 94.7% is provided, which is the electromagnetic wave absorption peak with the strongest absorption intensity. When F/Fₘis 6 (F=300 GHZ), an absorption rate of approximately 32.3% is provided, which is the electromagnetic wave absorption peak with the highest frequency.

With reference to FIG. 8C, FIG. 8C illustrates the absorption spectrum graph of the electromagnetic wave absorber 20 of Example 9, and the graph shows electromagnetic wave characteristic absorption peaks in multiple frequency bands. In detail, when F/Fₘ is 1 (F=50 GHZ), an electromagnetic wave absorption rate of approximately 64.3% is provided, which is the electromagnetic wave absorption peak with the strongest absorption intensity. When F/Fₘ is 1.43 (F=71.5 GHZ), an electromagnetic wave absorption rate of approximately 28.6% is provided. When F/Fₘ is 5.99 (F=299.5 GHZ), an absorption rate of approximately 50% is provided, which is the electromagnetic wave absorption peak with the highest frequency.

It can be known from the absorption spectrum graphs of the electromagnetic wave absorber 20 of the above Example 7 to Example 9 that in addition to the electromagnetic wave characteristic frequency of the plurality of magnetic material bodies M1, the electromagnetic wave absorber 20 is also added with a plurality of electromagnetic wave absorption frequencies due to the surface lattice resonance effect. Therefore, the electromagnetic wave absorber 20 of Example 7 to Example 9 may have electromagnetic wave characteristic absorption peaks in multiple frequency bands.

Further, it can also be known from the above absorption spectrum graphs of the electromagnetic wave absorber 20 of Example 7 to Example 9 that the electromagnetic wave absorption rate of the first electromagnetic wave characteristic absorption peak (F/Fₘ=50 GHZ) grows as fp in the relational expression 1 increases (i.e., the width a between magnetic material bodies M1 increases). Further, the absorption rate of F/Fₘ in the range of 1 to 6 becomes more average as fp in the relational expression 1 increases.

### Example 10

In Example 10, the structure of the electromagnetic wave absorber 20 shown in FIG. 2A and FIG. 2B is used. The parameters are substantially the same as those in Example 8, and the only difference is: (3) The dielectric coefficient of the substrate SB2 is 4.4. (8) The thickness mh of each magnetic material body M1 is 0.2 mm.

### Example 11

In Example 11, the structure of the electromagnetic wave absorber 20 shown in FIG. 2A and FIG. 2B is used. The parameters are substantially the same as those in Example 10, and the only difference is: (3) The dielectric coefficient of the substrate SB2 is 2.2.

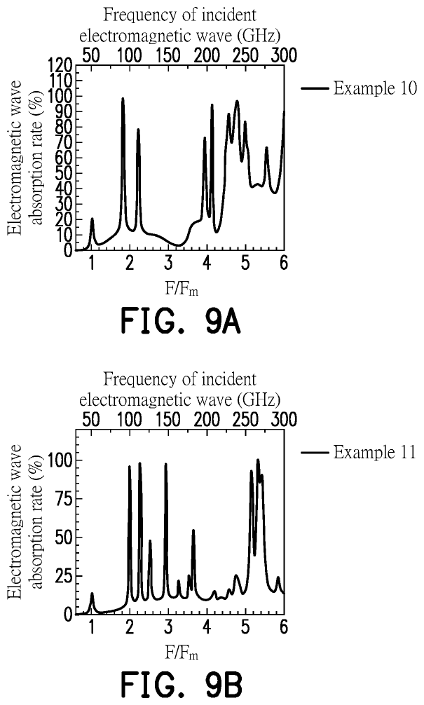

With the use of a terahertz time domain spectrometer, electromagnetic waves with different frequencies are incident on the electromagnetic wave absorber 20 of Example 10 to Example 11, so as to measure their electromagnetic wave absorption rates at each frequency, and the absorption spectrum graphs shown in FIG. 9A to FIG. 9B are produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 9A, FIG. 9A illustrates the absorption spectrum graph of the electromagnetic wave absorber 20 of Example 10, and the graph shows electromagnetic wave characteristic absorption peaks in multiple frequency bands. In detail, when F/Fₘ is 1 (F=50 GHZ), an electromagnetic wave absorption rate of approximately 20.6% is provided. When F/Fₘis 1.81 (F=90.5 GHZ), an absorption rate of approximately 98% is provided, which is the electromagnetic wave absorption peak with the strongest absorption intensity. When F/Fₘ is 6 (F=300 GHZ), an absorption rate of approximately 92.4% is provided, which is the electromagnetic wave absorption peak with the highest frequency.

With reference to FIG. 9B, FIG. 9B illustrates the absorption spectrum graph of the electromagnetic wave absorber 20 of Example 11, and the graph shows electromagnetic wave characteristic absorption peaks in multiple frequency bands. In detail, when F/Fₘ is 1 (F=50 GHZ), an electromagnetic wave absorption rate of approximately 14% is provided. When F/Fₘis 1.99 (F=99.5 GHZ), an electromagnetic wave absorption rate of approximately 94.7% is provided. When F/Fₘ is 5.32 (F=266 GHZ), an absorption rate of approximately 99% is provided, which is the electromagnetic wave absorption peak with the strongest absorption intensity. When F/Fₘ is 5.83 (F=291.5 GHZ), an absorption rate of approximately 24.2% is provided, which is the electromagnetic wave absorption peak with the highest frequency.

It can be known from the absorption spectrum graphs of the electromagnetic wave absorber 20 of the above Example 10 to Example 11 that in addition to the electromagnetic wave characteristic frequency of the plurality of magnetic material bodies M1, the electromagnetic wave absorber 20 is also added with a plurality of electromagnetic wave absorption frequencies due to the surface lattice resonance effect. Therefore, the electromagnetic wave absorber 20 of Example 10 to Example 11 may have electromagnetic wave characteristic absorption peaks in multiple frequency bands.

Further, from the above absorption spectrum graphs of the electromagnetic wave absorber 20 of Example 10 to Example 11, it can also be known that when the substrate SB2 has different dielectric coefficients, the electromagnetic wave absorber 20 of Example 10 to Example 11 can still have electromagnetic wave characteristic absorption peaks in multiple frequency bands.

### Example 12

The parameters in Example 12 are the same as those of the electromagnetic wave absorber 20 in Example 10, and the only difference is: the shape of each magnetic material body M1 is a triangular prism.

### Example 13

The parameters in Example 13 are the same as those of the electromagnetic wave absorber 20 in Example 10, and the only difference is: the shape of each magnetic material body M1 is a square prism.

### Example 14

The parameters in Example 14 are the same as those of the electromagnetic wave absorber 20 in Example 10, and the only difference is: the shape of each magnetic material body M1 is an octagonal prism.

### Example 15

The parameters in Example 15 are the same as those of the electromagnetic wave absorber 20 in Example 10, and the only difference is: the shape of each magnetic material body M1 is a cylindrical prism.

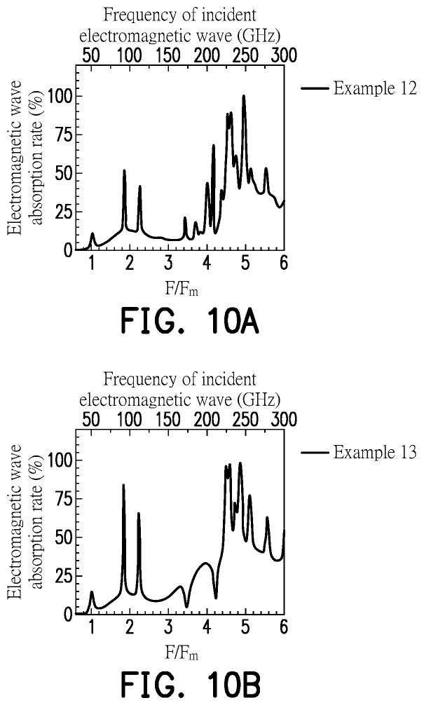

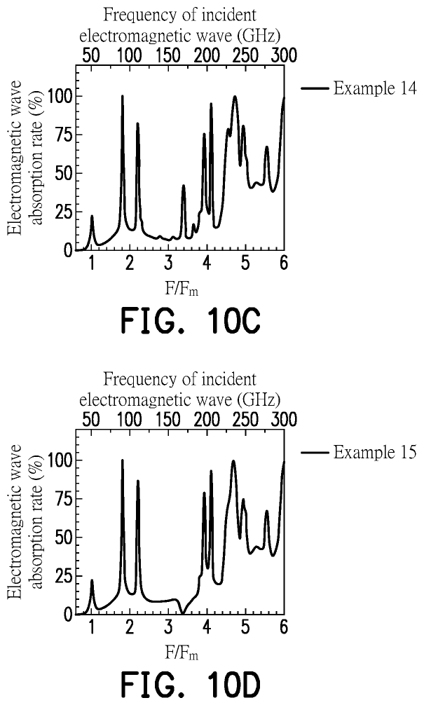

With the use of a terahertz time domain spectrometer, electromagnetic waves with different frequencies are incident on the electromagnetic wave absorber 20 of Example 12 to Example 15, so as to measure their electromagnetic wave absorption rates at each frequency, and the absorption spectrum graphs shown in FIG. 10A to FIG. 10D are produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 10A, FIG. 10A illustrates the absorption spectrum graph of the electromagnetic wave absorber 20 of Example 12, and the graph shows electromagnetic wave characteristic absorption peaks in multiple frequency bands. In detail, when F/Fₘ is 1 (F=50 GHZ), an electromagnetic wave absorption rate of approximately 11.14% is provided. When F/Fₘ is 1.85 (F=92.5 GHZ), an absorption rate of approximately 51.3% is provided. When F/Fₘ is 4.96 (F=248 GHZ), an absorption rate of approximately 99.9% is provided, which is the electromagnetic wave absorption peak with the strongest absorption intensity. When F/Fₘ is 5.53 (F=276.5 GHZ), an absorption rate of approximately 52.7% is provided, which is the electromagnetic wave absorption peak with the highest frequency.

With reference to FIG. 10B, FIG. 10B illustrates the absorption spectrum graph of the electromagnetic wave absorber 20 of Example 13, and the graph shows electromagnetic wave characteristic absorption peaks in multiple frequency bands. In detail, when F/Fₘ is 1 (F=50 GHZ), an electromagnetic wave absorption rate of approximately 14.78% is provided. When F/Fₘ is 1.83 (F=91.5 GHZ), an electromagnetic wave absorption rate of approximately 83.84% is provided. When F/Fₘ is 4.86 (F=243 GHZ), an absorption rate of approximately 98% is provided, which is the electromagnetic wave absorption peak with the strongest absorption intensity. When F/Fₘ is 5.55 (F=277.5 GHZ), an absorption rate of approximately 62.59% is provided, which is the electromagnetic wave absorption peak with the highest frequency.

With reference to FIG. 10C, FIG. 10C illustrates the absorption spectrum graph of the electromagnetic wave absorber 20 of Example 14, and the graph shows electromagnetic wave characteristic absorption peaks in multiple frequency bands. In detail, when F/Fₘ is 1 (F=50 GHZ), an electromagnetic wave absorption rate of approximately 22.85% is provided. When F/Fₘ is 1.81 (F=90.5 GHZ), an electromagnetic wave absorption rate of approximately 99.68% is provided, which is the electromagnetic wave absorption peak with the strongest absorption intensity. When F/Fₘ is 5.98 (F=299 GHZ), an absorption rate of approximately 97.87% is provided, which is the electromagnetic wave absorption peak with the highest frequency.

With reference to FIG. 10D, FIG. 10D illustrates the absorption spectrum graph of the electromagnetic wave absorber 20 of Example 15, and the graph shows electromagnetic wave characteristic absorption peaks in multiple frequency bands. In detail, when F/Fₘ is 1 (F=50 GHZ), an electromagnetic wave absorption rate of approximately 25.38% is provided. When F/Fₘ is 5.95 (F=297.5 GHZ), an absorption rate of approximately 99.74% is provided, which is the electromagnetic wave absorption peak with the strongest absorption intensity and highest frequency.

It can be known from the absorption spectrum graphs of the electromagnetic wave absorber 20 of the above Example 12 to Example 15 that in addition to the electromagnetic wave characteristic frequency of the plurality of magnetic material bodies M1, the electromagnetic wave absorber 20 is also added with a plurality of electromagnetic wave absorption frequencies due to the surface lattice resonance effect. Therefore, the electromagnetic wave absorber 20 of Example 12 to Example 15 may have electromagnetic wave characteristic absorption peaks in multiple frequency bands.

Further, from the above absorption spectrum graphs of the electromagnetic wave absorber 20 of Example 12 to Example 15, it can also be known that when the shapes of the magnetic material bodies M1 are different,
the electromagnetic wave absorber 20 of Example 12 to Example 15 may still have electromagnetic wave characteristic absorption peaks in multiple frequency bands.

### Example 16

In Example 16, the structure of the electromagnetic wave absorber 30 shown in FIG. 3 is used, and the following parameters are provided.

(1) The electromagnetic wave characteristic frequency of the magnetic material bodies M2 is 50 GHz (twice the electromagnetic wave characteristic frequency is 100 GHz). (2) The dielectric coefficient of each magnetic material body M2 is 4. (3) The dielectric coefficient of the substrate SB2 is 4.4. (4) The magnetic permeability coefficient of the substrate SB2 is 1. (5) fp in the relational expression 1 used to express the width of each magnetic material body M2 is 0.15. (6) sp in the relational expression 2 used to express the pitch p between adjacent magnetic material bodies M2 is 1. (7) The thickness h of the substrate SB2 is 0.4 mm. (8) The thickness mh of each magnetic material body M2 is 0.4 mm. (9) The ratio of the area of the bottom surface S1 to the area of the top surface S2 of each magnetic material body M2 (i.e., the ratio of the square of the width a1 to the square of the width a2) is 1.

### Example 17

In Example 17, the structure of the electromagnetic wave absorber 30 shown in FIG. 3 is used. The parameters are substantially the same as those in Example 16, and the only difference is: (9) The ratio of the area of the bottom surface S1 to the area of the top surface S2 of each magnetic material body M2 (i.e., the ratio of the square of the width a1 to the square of the width a2) is 2.25.

### Example 18

In Example 18, the structure of the electromagnetic wave absorber 30 shown in FIG. 3 is used. The parameters are substantially the same as those in Example 16, and the only difference is: (9) The ratio of the area of the bottom surface S1 to the area of the top surface S2 of each magnetic material body M2 (i.e., the ratio of the square of the width a1 to the square of the width a2) is 4.

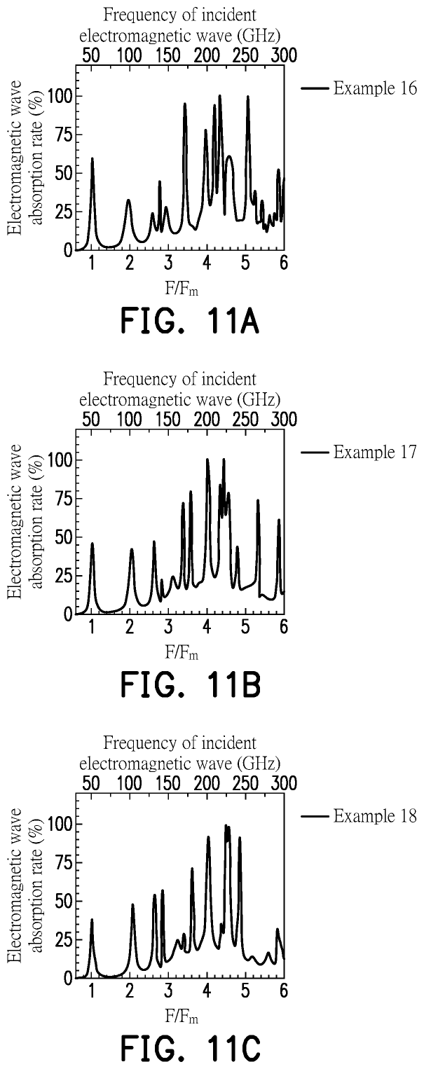

With the use of a terahertz time domain spectrometer, electromagnetic waves with different frequencies are incident on the electromagnetic wave absorber 30 of Example 16 to Example 18, so as to measure their electromagnetic wave absorption rates at each frequency, and the absorption spectrum graphs shown in FIG. 11A to FIG. 11C are produced. The x-axis is a ratio of the incident electromagnetic wave frequency to the electromagnetic wave characteristic frequency of the magnetic material bodies M2 (F/Fₘ), and the y-axis is an absorption rate of the incident electromagnetic wave.

With reference to FIG. 11A, FIG. 11A illustrates the absorption spectrum graph of the electromagnetic wave absorber 30 of Example 16, and the graph shows electromagnetic wave characteristic absorption peaks in multiple frequency bands. In detail, when F/Fₘ is 1 (F=50 GHZ), an electromagnetic wave absorption rate of approximately 59.6% is provided. When F/Fₘ is 1.96 (F=98 GHZ), an electromagnetic wave absorption rate of approximately 33.6% is provided. When F/Fₘ is 4.33 (F=216.5 GHZ), an absorption rate of approximately 99.43% is provided, which is the electromagnetic wave absorption peak with the strongest absorption intensity. When F/Fₘ is 6 (F=300 GHZ), an absorption rate of approximately 46.9% is provided, which is the electromagnetic wave absorption peak with the highest frequency.

With reference to FIG. 11B, FIG. 11B illustrates the absorption spectrum graph of the electromagnetic wave absorber 30 of Example 17, and the graph shows electromagnetic wave characteristic absorption peaks in multiple frequency bands. In detail, when F/Fₘ is 1 (F=50 GHZ), an electromagnetic wave absorption rate of approximately 45.49% is provided. When F/Fₘ is 2.04 (F=102 GHZ), an electromagnetic wave absorption rate of approximately 42.22% is provided. When F/Fₘ is 4.43 (F=221.5 GHZ), an absorption rate of approximately 92.29% is provided, which is the electromagnetic wave absorption peak with the strongest absorption intensity. When F/Fₘ is 5.85 (F=292.5 GHZ), an absorption rate of approximately 60.43% is provided, which is the electromagnetic wave absorption peak with the highest frequency.

With reference to FIG. 11C, FIG. 11C illustrates the absorption spectrum graph of the electromagnetic wave absorber 30 of Example 18, and the graphs shows electromagnetic wave characteristic absorption peaks in multiple frequency bands. In detail, when F/Fₘ is 1 (F=50 GHZ), an electromagnetic wave absorption rate of approximately 38.07% is provided. When F/Fₘ is 2.08 (F=104 GHZ), an electromagnetic wave absorption rate of approximately 48.37% is provided. When F/Fₘ is 4.51 (F=225.5 GHZ), an absorption rate of approximately 99.10% is provided, which is the electromagnetic wave absorption peak with the strongest absorption intensity. When F/Fₘ is 5.83 (F=291.5 GHZ), an absorption rate of approximately 31.85% is provided, which is the electromagnetic wave absorption peak with the highest frequency.

It can be known from the absorption spectrum graphs of the electromagnetic wave absorber 30 of the above Example 16 to Example 18 that in addition to the electromagnetic wave characteristic frequency (F) of the plurality of magnetic material bodies M1, the electromagnetic wave absorber 30 is also added with a plurality of electromagnetic wave absorption frequencies due to the surface lattice resonance effect. Therefore, the electromagnetic wave absorber 30 of Example 16 to Example 18 may have electromagnetic wave characteristic absorption peaks in multiple frequency bands.

Further, it can also be known from the above absorption spectrum graphs of the electromagnetic wave absorber 20 of Example 16 to Example 18 that the electromagnetic wave absorption rate of the first electromagnetic wave characteristic absorption peak (F/Fₘ=50 GHZ) drops as the ratio of the area of the bottom surface S1 to the area of the top surface S2 of each magnetic material body M2 increases. However, the electromagnetic wave absorber 30 of Example 16 to Example 18 may still have electromagnetic wave characteristic absorption peaks in multiple frequency bands.

### Example 19

In Example 19, the structure of the electromagnetic wave absorber 40 shown in FIG. 4A and FIG. 4B is used, and the following parameters are provided.

(1) The electromagnetic wave characteristic frequency of the magnetic material bodies M1 is 50 GHz (twice the electromagnetic wave characteristic frequency is 100 GHz). (2) The dielectric coefficient of each magnetic material body M1 is 4. (3) The dielectric coefficient of the substrate SB3 is 4.4. (4) The magnetic permeability coefficient of the substrate SB3 is 1. (5) fp in the relational expression 1 used to express the width of each magnetic material body M1 is 0.25. (6) The pitch p between adjacent magnetic material bodies M1 is 2.848. (7) The thickness h of the substrate SB3 is 2.8 mm, where a thickness sh of the third substrate SB33 is 2 mm. (8) The thickness mh of each magnetic material body M2 is 0.2 mm.

### Example 20

In Example 20, the structure of the electromagnetic wave absorber 40 shown in FIG. 4A and FIG. 4B is used. The parameters are substantially the same as those in Example 19, and the only difference is: (7) The thickness h of the substrate SB3 is 4.8 mm, where the thickness sh of the third substrate SB33 is 4 mm.

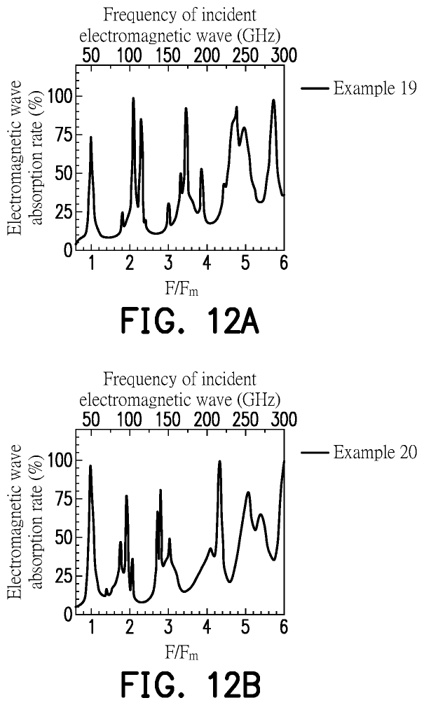

With the use of a terahertz time domain spectrometer, electromagnetic waves with different frequencies are incident on the electromagnetic wave absorber 40 of Example 19 to Example 20, so as to measure their electromagnetic wave absorption rates at each frequency, and the absorption spectrum graphs shown in FIG. 12A to FIG. 12B are produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 12A, FIG. 12A illustrates the absorption spectrum graph of the electromagnetic wave absorber 40 of Example 19, and the graph shows electromagnetic wave characteristic absorption peaks in multiple frequency bands. In detail, when F/Fₘ is 1 (F=50 GHZ), an electromagnetic wave absorption rate of approximately 74.72% is provided. When F/Fₘ is 1.8 (F=90 GHZ), an electromagnetic wave absorption rate of approximately 24.45% is provided. When F/Fₘ is 2.09 (F=104.5 GHZ), an absorption rate of approximately 98.12% is provided, which is the electromagnetic wave absorption peak with the strongest absorption intensity. When F/Fₘ is 5.73 (F=286.5 GHZ), an absorption rate of approximately 97.72% is provided, which is the electromagnetic wave absorption peak with the highest frequency.

With reference to FIG. 12B, FIG. 12B illustrates the absorption spectrum graph of the electromagnetic wave absorber 40 of Example 20, and the graph shows electromagnetic wave characteristic absorption peaks in multiple frequency bands. In detail, when F/Fₘ is 1 (F=50 GHZ), an electromagnetic wave absorption rate of approximately 96.52% is provided. When F/Fₘ is 1.39 (F=69.5 GHZ), an electromagnetic wave absorption rate of approximately 16.22% is provided. When F/Fₘ is 4.31 (F=215.5 GHZ), an absorption rate of approximately 98.75% is provided, which is the electromagnetic wave absorption peak with the strongest absorption intensity. When F/Fₘ is 5.96 (F=298 GHZ), an absorption rate of approximately 98.31% is provided, which is the electromagnetic wave absorption peak with the highest frequency.

It can be known from the absorption spectrum graphs of the electromagnetic wave absorber 40 of the above Example 19 to Example 20 that in addition to the electromagnetic wave characteristic frequency of the plurality of magnetic material bodies M1, the electromagnetic wave absorber 40 is also added with a plurality of electromagnetic wave absorption frequencies due to the surface lattice resonance effect. Therefore, the electromagnetic wave absorber 40 of Example 19 to Example 20 may have electromagnetic wave characteristic absorption peaks in multiple frequency bands.

Further, it can also be known from the above absorption spectrum graphs of the electromagnetic wave absorber 40 of Example 19 to Example 20 that the electromagnetic wave absorption rate of the first electromagnetic wave characteristic absorption peak (F/Fₘ=50 GHZ) grows as the thickness sh of the third substrate SB33 in the substrate SB3 increases.

### Example 21

In Example 21, the structure of the electromagnetic wave absorber 50 shown in FIG. 5A and FIG. 5B is used, and the following parameters are provided.

(1) The electromagnetic wave characteristic frequency of the magnetic material bodies M1 is 50 GHz (twice the electromagnetic wave characteristic frequency is 100 GHz). (2) The dielectric coefficient of each magnetic material body M1 is 4. (5) fp in the relational expression 1 used to express the width of each magnetic material body M1 is 0.15. (6) sp in the relational expression 2 used to express the pitch p between adjacent magnetic material bodies M1 is 1. (7) The thickness h of the substrate SB4 is 0.4 mm. (8) The thickness mh of each magnetic material body M2 is 0.2 mm.

### Example 22

In Example 22, the structure of the electromagnetic wave absorber 50 shown in FIG. 5A and FIG. 5B is used. The parameters are substantially the same as those in Example 21, and the only difference is: (2) The dielectric coefficient of each magnetic material body M1 is 7.

### Example 23

In Example 23, the structure of the electromagnetic wave absorber 50 shown in FIG. 5A and FIG. 5B is used. The parameters are substantially the same as those in Example 21, and the only difference is: (2) The dielectric coefficient of each magnetic material body M1 is 12.

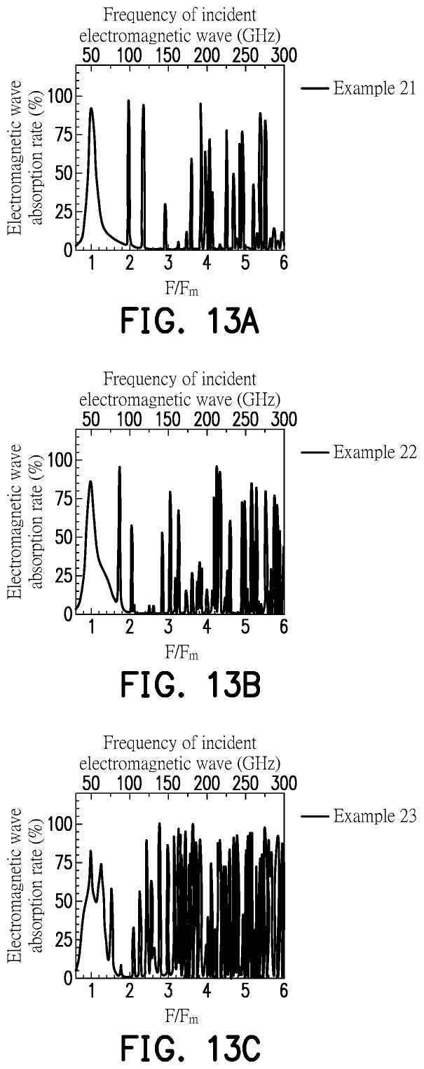

With the use of a terahertz time domain spectrometer, electromagnetic waves with different frequencies are incident on the electromagnetic wave absorber 50 of Example 21 to Example 23, so as to measure their electromagnetic wave absorption rates at each frequency, and the absorption spectrum graphs shown in FIG. 13A to FIG. 13C are produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 13A, FIG. 13A illustrates the absorption spectrum graph of the electromagnetic wave absorber 50 of Example 21, and the graph shows electromagnetic wave characteristic absorption peaks in multiple frequency bands. In detail, when F/Fₘ is 1 (F=50 GHZ), an electromagnetic wave absorption rate of approximately 92.56% is provided. When F/Fₘ is 1.96 (F=98 GHZ), an electromagnetic wave absorption rate of approximately 97.31% is provided, which is the electromagnetic wave absorption peak with the strongest absorption intensity. When F/Fₘ is 5.98 (F=299 GHZ), an absorption rate of approximately 3.5% is provided, which is the electromagnetic wave absorption peak with the highest frequency.

With reference to FIG. 13B, FIG. 13B illustrates the absorption spectrum graph of the electromagnetic wave absorber 50 of Example 22, and the graph shows electromagnetic wave characteristic absorption peaks in multiple frequency bands. In detail, when F/Fₘ is 1 (F=50 GHZ), an electromagnetic wave absorption rate of approximately 88.60% is provided. When F/Fₘ is 1.74 (F=87 GHZ), an electromagnetic wave absorption rate of approximately 95.41% is provided. When F/Fₘ is 4.27 (F=213.5 GHZ), an absorption rate of approximately 95.73% is provided, which is the electromagnetic wave absorption peak with the strongest absorption intensity. When F/Fₘ is 5.99 (F=299.5 GHZ), an absorption rate of approximately 43.52% is provided, which is the electromagnetic wave absorption peak with the highest frequency.

With reference to FIG. 13C, FIG. 13C illustrates the absorption spectrum graph of the electromagnetic wave absorber 50 of Example 23, and the graph shows electromagnetic wave characteristic absorption peaks in multiple frequency bands. In detail, when F/Fₘ is 1 (F=50 GHZ), an electromagnetic wave absorption rate of approximately 83.67% is provided. When F/Fₘ is 1.25 (F=62.5 GHZ), an electromagnetic wave absorption rate of approximately 74.78% is provided. When F/Fₘ is 3.63 (F=181.5 GHZ), an absorption rate of approximately 99.69% is provided, which is the electromagnetic wave absorption peak with the strongest absorption intensity. When F/Fₘ is 5.97 (F=298.5 GHZ), an absorption rate of approximately 96.83% is provided, which is the electromagnetic wave absorption peak with the highest frequency.

It can be known from the absorption spectrum graphs of the electromagnetic wave absorber 50 of the above Example 21 to Example 23 that in addition to the electromagnetic wave characteristic frequency of the plurality of magnetic material bodies M1, the electromagnetic wave absorber 50 is also added with a plurality of electromagnetic wave absorption frequencies due to the surface lattice resonance effect. Therefore, the electromagnetic wave absorber 50 of Example 21 to Example 23 may have electromagnetic wave characteristic absorption peaks in multiple frequency bands.

Further, it can also be known from the above absorption spectrum graphs of the electromagnetic wave absorber 50 of Example 21 to Example 23 that the electromagnetic wave absorption rate of the first electromagnetic wave characteristic absorption peak (F/Fₘ=50 GHZ) grows as the thickness h of the substrate SB4 increases.

### Example 24

In Example 24, the structure of the electromagnetic wave absorber 10 shown in FIG. 1A and FIG. 1B is used. The parameters are substantially the same as those in Example 2, and the only difference is: (1) The electromagnetic wave characteristic frequency of the magnetic material bodies M1 is 0.5 GHz (twice the electromagnetic wave characteristic frequency is 1 GHz).

### Example 25

In Example 25, the structure of the electromagnetic wave absorber 10 shown in FIG. 1A and FIG. 1B is used. The parameters are substantially the same as those in Example 2, and the only difference is: (1) The electromagnetic wave characteristic frequency of the magnetic material bodies M1 is 150 GHz (twice the electromagnetic wave characteristic frequency is 300 GHz).

### Example 26

In Example 26, the structure of the electromagnetic wave absorber 10 shown in FIG. 1A and FIG. 1B is used. The parameters are substantially the same as those in Example 2, and the only difference is: (1) The electromagnetic wave characteristic frequency of the magnetic material bodies M1 is 250 GHz (twice the electromagnetic wave characteristic frequency is 500 GHz).

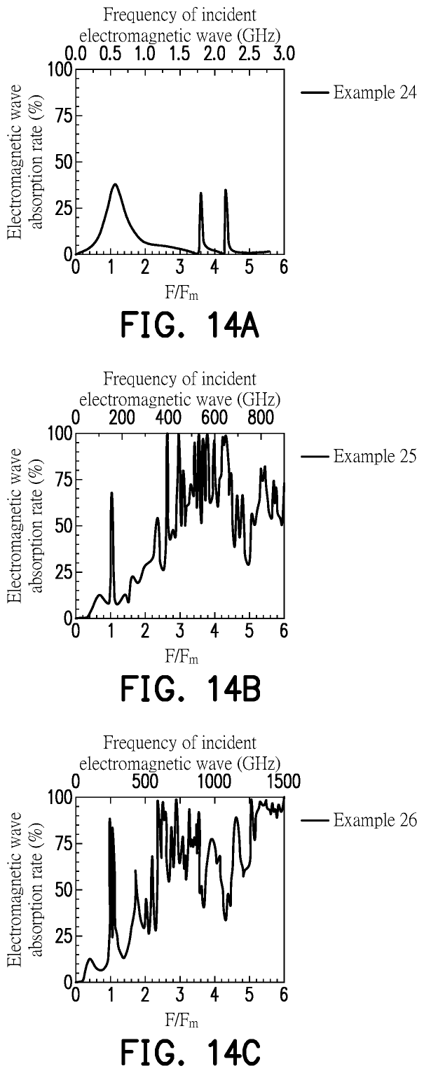

With the use of a terahertz time domain spectrometer, electromagnetic waves with different frequencies are incident on the electromagnetic wave absorber 10 of Example 24 to Example 26, so as to measure their electromagnetic wave absorption rates at each frequency, and the absorption spectrum graphs shown in FIG. 14A to FIG. 14C are produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 14A, FIG. 14A illustrates the absorption spectrum graph of the electromagnetic wave absorber 10 of Example 24, and the graph shows electromagnetic wave characteristic absorption peaks in multiple frequency bands. In detail, when F/Fₘ is 1 (F=0.5 GHZ), an electromagnetic wave absorption rate of approximately 37.4% is provided, which is the electromagnetic wave absorption peak with the strongest absorption intensity. When F/Fₘ is 3.6 (F=1.8 GHZ), an electromagnetic wave absorption rate of approximately 33% is provided. When F/Fₘ is 4.32 (F=2.16 GHZ), an absorption rate of approximately 34.7% is provided, which is the electromagnetic wave absorption peak with the highest frequency.

With reference to FIG. 14B, FIG. 14B illustrates the absorption spectrum graph of the electromagnetic wave absorber 10 of Example 25, and the graph shows electromagnetic wave characteristic absorption peaks in multiple frequency bands. In detail, when F/Fₘ is 1 (F=150 GHZ), an electromagnetic wave absorption rate of approximately 67.95% is provided. When F/Fₘ is 2.33 (F=349.5 GHZ), an electromagnetic wave absorption rate of approximately 54.13% is provided. When F/Fₘ is 3.78 (F=567 GHZ), an absorption rate of approximately 99.95% is provided, which is the electromagnetic wave absorption peak with the strongest absorption intensity. When F/Fₘ is 6 (F=900 GHZ), an absorption rate of approximately 72% is provided, which is the electromagnetic wave absorption peak with the highest frequency.

With reference to FIG. 14C, FIG. 14C illustrates the absorption spectrum graph of the electromagnetic wave absorber 10 of Example 26, and the graph shows electromagnetic wave characteristic absorption peaks in multiple frequency bands. In detail, when F/Fₘ is 1 (F=250 GHZ), an electromagnetic wave absorption rate of approximately 88.57% is provided. When F/Fₘ is 1.03 (F=257.5 GHZ), an electromagnetic wave absorption rate of approximately 83.46% is provided. When F/Fₘ is 5.96 (F=1490 GHZ), an absorption rate of approximately 99.96% is provided, which is the electromagnetic wave absorption peak with the strongest absorption intensity and highest frequency.

It can be known from the absorption spectrum graphs of the electromagnetic wave absorber 10 of the above Example 24 to Example 26 that in addition to the electromagnetic wave characteristic frequency of the plurality of magnetic material bodies M1, the electromagnetic wave absorber 10 is also added with a plurality of electromagnetic wave absorption frequencies due to the surface lattice resonance effect. Therefore, the electromagnetic wave absorber 40 of Example 24 to Example 26 may have electromagnetic wave characteristic absorption peaks in multiple frequency bands.

Further, from the above absorption spectrum graphs of the electromagnetic wave absorber 10 of Example 24 to Example 26, it can be used to absorb incident electromagnetic waves with different frequencies.

### Example 27

In Example 27, the structure of the electromagnetic wave absorber 10 shown in FIG. 1A and FIG. 1B is used. The parameters are substantially the same as those in Example 2, and the only difference is: (6) The pitch p is 2.02 mm. (8) The thickness mh of each magnetic material body M1 is 0.2 to 0.3 mm.

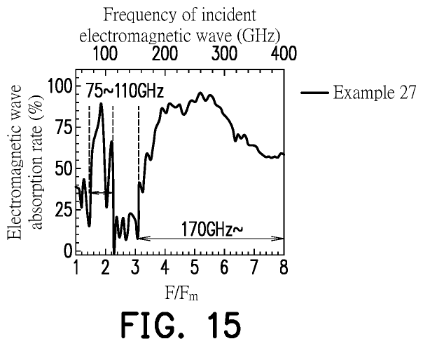

With the use of a terahertz time domain spectrometer (“TeraFlash pro” system from Toptica Company), electromagnetic waves with different frequencies are incident on the electromagnetic wave absorber 10 of Example 27, so as to measure their electromagnetic wave absorption rates at each frequency, and the absorption spectrum graphs shown in FIG. 15 is produced. The x-axis is a ratio of the incident electromagnetic wave frequency to the electromagnetic wave characteristic frequency of the magnetic material bodies M1 (F/Fₘ), and the y-axis is an absorption rate of the incident electromagnetic wave.

With reference to FIG. 6C, FIG. 6C illustrates the absorption spectrum graph of the electromagnetic wave absorber 10 of Example 27, and the graph shows electromagnetic wave characteristic absorption peaks in multiple frequency bands (especially in the frequency band where F is 75 GHZ to 110 GHZ and the frequency band where F is greater than or equal to 170 GHZ). In detail, when F/Fₘ is 1 (F=50 GHZ), an electromagnetic wave absorption rate of approximately 45% is provided. When F/Fₘ is 5.2 (F=260 GHZ), an electromagnetic wave absorption rate of approximately 95% is provided, which is the electromagnetic wave absorption peak with the strongest absorption intensity. Further, the electromagnetic wave absorber 10 of Example 27 still has an electromagnetic wave absorption rate of 65% when F/Fₘ is 8 (F=400 GHZ).

It can be known from the absorption spectrum graph of the electromagnetic wave absorber 10 of the above Example 27 that in addition to the electromagnetic wave characteristic frequency of the plurality of magnetic material bodies M1, the electromagnetic wave absorber 10 is also added with a plurality of electromagnetic wave absorption frequencies due to the surface lattice resonance effect. Therefore, the electromagnetic wave absorber 10 of Example 27 may have electromagnetic wave characteristic absorption peaks in multiple frequency bands.

Further, from the above absorption spectrum graph of the electromagnetic wave absorber 10 of Example 27, it can be used to absorb incident electromagnetic waves with different frequencies.

### Comparative Example 1

The electromagnetic wave absorber used in Comparative Example 1 has a structure formed by one layer of magnetic material body, has a rectangular shape, and provides the following parameters.

(1) The electromagnetic wave characteristic frequency Fₘ of the magnetic material body is 50 GHz. (2) The dielectric coefficient of the magnetic material body is 4. (5) A length and the thickness of the magnetic material body are each 9 mm. (8) The thickness of the magnetic material body is 0.4 mm.

### Comparative Example 2

The electromagnetic wave absorber used in Comparative Example 2 has a structure in which one layer of magnetic material body and one layer of substrate are stacked on each other, has a rectangular shape, and provides the following parameters.

(1) The electromagnetic wave characteristic frequency of the magnetic material body is 50 GHz. (2) The dielectric coefficient of the magnetic material body is 4. (3) The dielectric coefficient of the substrate is 4.4. (4) The magnetic permeability coefficient of the substrate is 1. (5) The length and the thickness of the magnetic material body are each 9 mm. (7) The thickness h of the substrate is 0.4 mm. (8) The thickness of the magnetic material body is 0.4 mm.

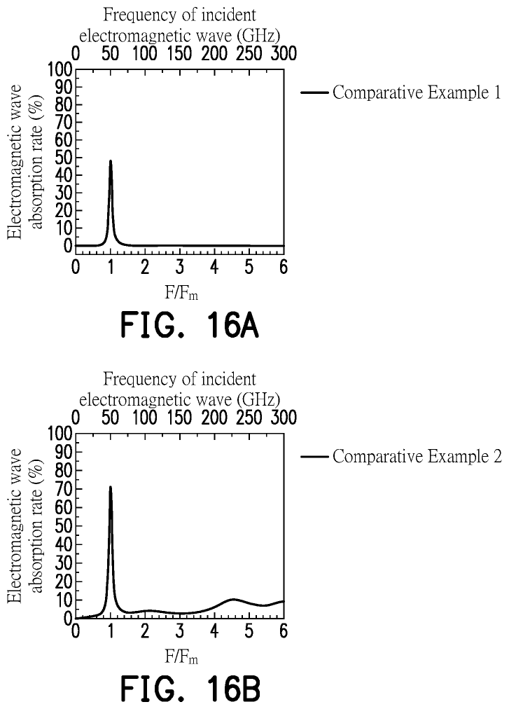

With the use of a terahertz time domain spectrometer, electromagnetic waves with different frequencies are incident on the electromagnetic wave absorber of Comparative Example 1 and Comparative Example 2, so as to measure their electromagnetic wave absorption rates at each frequency, and the absorption spectrum graphs shown in FIG. 16A and FIG. 16B are produced. The x-axis is the ratio of the incident electromagnetic wave frequency to the electromagnetic wave characteristic frequency of the magnetic material body (F/Fₘ), and the y-axis is the absorption rate of the incident electromagnetic wave.

With reference to FIG. 16A, FIG. 16A illustrates the absorption spectrum graph of the electromagnetic wave absorber of Comparative Example 1, and the graph shows only one electromagnetic wave characteristic absorption peak in one frequency band. That is, when F/Fₘis 1 (F=50 GHZ), an electromagnetic wave absorption rate of approximately 48.1% is provided.

With reference to FIG. 16B, FIG. 16B illustrates the absorption spectrum graph of the electromagnetic wave absorber of Comparative Example 2, and the graph shows only one electromagnetic wave characteristic absorption peak in one frequency band. That is, when F/Fₘ is 1 (F=50 GHZ), an electromagnetic wave absorption rate of approximately 70.5% is provided.

In view of the foregoing, by arranging the plurality of magnetic material bodies on the substrate in an array, the electromagnetic wave absorber provided by the disclosure can absorb electromagnetic waves in at least two frequency bands. In detail, the electromagnetic wave absorber provided by the disclosure can absorb electromagnetic waves with the same or similar frequency as the electromagnetic wave characteristic frequency of the magnetic material bodies. Further, a surface lattice resonance effect will occur between adjacent magnetic material bodies. As such, the electromagnetic wave absorber provided by the disclosure can have multiple electromagnetic wave absorption frequencies in addition to the abovementioned electromagnetic wave characteristic frequency, and therefore, can absorb high-frequency electromagnetic waves in other frequency bands (the frequencies of which are greater than the electromagnetic wave characteristic frequency of the magnetic material bodies). Based on the above, the electromagnetic wave absorber of the disclosure can be used in the next-generation communication systems to reduce the phenomenon of electromagnetic interference generated in the systems.

What is claimed is:

1. An electromagnetic wave absorber, comprising:
a substrate; and
a plurality of magnetic material bodies disposed on the substrate in an array, so that the electromagnetic wave absorber has a plurality of electromagnetic wave absorption frequencies in addition to an electromagnetic wave characteristic frequency of the plurality of magnetic material bodies,
wherein a ratio of one of the plurality of electromagnetic wave absorption frequencies to the electromagnetic wave characteristic frequency is greater than 1 and less than or equal to 6.

2. The electromagnetic wave absorber according to claim 1, wherein a dielectric coefficient of the substrate is 1 to 50.

3. The electromagnetic wave absorber according to claim 1, wherein the substrate comprises a multi-layer structure.

4. The electromagnetic wave absorber according to claim 3, wherein the substrate comprises a first substrate and a second substrate stacked on each other, and the plurality of magnetic material bodies are disposed on the second substrate.

5. The electromagnetic wave absorber according to claim 4, wherein a material of the first substrate comprises a conductive material, and a material of the second substrate comprises resin.

6. The electromagnetic wave absorber according to claim 4, wherein a material of the first substrate comprises a conductive material, and a material of the second substrate is the same as a material of the plurality of magnetic material bodies.

7. The electromagnetic wave absorber according to claim 3, wherein substrate comprises a first substrate, a second substrate, and a third substrate that are stacked on one another, and the plurality of magnetic material bodies are disposed on the third substrate.

8. The electromagnetic wave absorber according to claim 7, wherein a material of the first substrate comprises a conductive material, a material of the second substrate comprises resin, and a material of the third substrate is the same as a material of the plurality of magnetic material bodies.

9. The electromagnetic wave absorber according to claim 1, wherein a thickness of the substrate is 0.05 mm to 50 mm.

10. The electromagnetic wave absorber according to claim 1, wherein the electromagnetic wave characteristic frequency of the plurality of magnetic material bodies is 0.1 MHz to 1 THz.

11. The electromagnetic wave absorber according to claim 1, wherein a shape of each magnetic material body comprises a polygonal prism shape, a cylindrical prism shape, a polygonal cone shape, a conical shape, or a combination thereof.

12. The electromagnetic wave absorber according to claim 11, wherein polygonal shapes of the polygonal prism shape and the polygonal cone shape comprise a trigonal shape, a quadrilateral shape, a hexagonal shape, an octagonal shape, or a dodecagonal shape.

13. The electromagnetic wave absorber according to claim 1, wherein a thickness of each magnetic material body is 0.01 mm to 50 mm.

14. The electromagnetic wave absorber according to claim 1, wherein a width of each magnetic material body conforms to:
a=λ_{F}_{ₘ}*fp, where a is the width of the magnetic material body, λ_{F}_{ₘ} is a wavelength of the electromagnetic wave characteristic frequency Fₘ of the plurality of magnetic material bodies, and fp is 0.01 to 50.

15. The electromagnetic wave absorber according to claim 1, wherein a pitch is provided between adjacent magnetic material bodies and conforms to:
p=sp*λ_{F}_{ₛ}/(\sqrt{(εₛμₛ)}, where p is the pitch between adjacent magnetic material bodies, λ_{F}_{ₛ} is a wavelength of twice the electromagnetic wave characteristic frequency of the magnetic material bodies, εₛ is a dielectric coefficient of the substrate, μₛ is a magnetic permeability coefficient of the substrate, and sp is 0.1 to 2.

16. The electromagnetic wave absorber according to claim 1, wherein a ratio of a cross-sectional area of a bottom surface to a cross-sectional area of a top surface of the plurality of magnetic material bodies is ≥1.

17. The electromagnetic wave absorber according to claim 1, wherein dielectric coefficients of the plurality of magnetic material bodies range from 1 to 50.
